(19) United States
(12) Patent Application Publication
(10) Pub. No.: US 2026/0169065 A1
(43) Pub. Date: Jun. 18, 2026

(54) WIRELESS HARDWARE TROJAN DETECTION

(71) Applicants: Eduardo Antonio Rojas, Port Orange, FL (US); Harkiran Bhullar, Easton, PA (US); Rachel Swan, Daytona Beach, FL (US)

(72) Inventors: Eduardo Antonio Rojas, Port Orange, FL (US); Harkiran Bhullar, Easton, PA (US); Rachel Swan, Daytona Beach, FL (US)

(21) Appl. No.: 19/418,292

(22) Filed: Dec. 12, 2025

Related U.S. Application Data
(60) Provisional application No. 63/733,906, filed on Dec. 13, 2024.

(51) Int. Cl. G01R 31/317; H04B 17/00

(52) U.S. Cl. CPC G01R 31/31719; H04B 17/0085

(57) ABSTRACT

Unintended or malicious antennas, or “Hardware Trojans” (HTs) in general, can pose threats to electronic systems if left undetected or unmitigated. The present subject matter can be used to identify a potential presence of HTs in systems as a security mechanism, such as before the HTs can pose any threats. The present subject matter can be integrated as a scanner element in a system that actively checks the environment and provides an indication of a count or presence of antennas or other indicia of HTs. As an example, RADAR scanning can be used to transmit electromagnetic signals and record corresponding reflected signals. These measurements can provide an indication of unique fingerprints of one or more antennas embedded in the captured signal. The measurements can be provided to a trained machine-learning model that can detect a presence of the antennas or HTs, such as identifying a count of antennas present.

### CLAIM OF PRIORITY

This patent application claims the benefit of priority of Rojas et al., U.S. Provisional Patent Application No. 63/733,906, titled “WIRELESS HARDWARE TROJAN DETECTION,” filed on Dec. 13, 2024 (Attorney Docket No. 4568.024PRV), which is hereby incorporated by reference herein in its entirety.

### STATEMENT REGARDING FEDERALLY SPONSORED RESEARCH OR DEVELOPMENT

This invention was made with government support under award 1944599 awarded by the National Science Foundation. The government has certain rights in the invention.

### FIELD OF THE DISCLOSURE

This document pertains generally, but not by way of limitation, to detection of physical layer security threats, such as involving unwanted or unauthorized wireless hardware present in a system, and more particularly, to techniques for detection of unwanted or unauthorized wireless hardware (e.g., “Hardware Trojans”) using a wireless technique.

### BACKGROUND

Electronic systems are ubiquitous in everyday life, such as used in infrastructure and consumer products. Such electronic systems, including “embedded” systems, can include or form a portion of communications systems (e.g., wireless systems), remote monitoring systems, or supervisory control systems, as illustrative examples. A life cycle for electronic systems, such as related to hardware included as a portion of an electronic system, generally involves design, manufacturing, integration, testing, deployment, and even maintenance, and such a life cycle can involve many entities. These entities can be spread across the world. The breadth of different entities and opacity regarding their internal structure, controls, and practices can make resulting systems susceptible to tampering (e.g., a “physical layer attack”), such as where unwanted sections of hardware are added to the system or enabled within the system, with malicious intent.

### SUMMARY OF THE DISCLOSURE

As described herein, the present subject matter can include use of electromagnetic waves to wirelessly detect the presence of unwanted hardware, including antennas. Unwanted hardware in an electronic system can be referred to as a “Hardware Trojan (HT).” For example, electronic systems such as wireless systems (including infrastructure, industrial, and consumer devices) can provide satellite and mobile communications, television and radio broadcasting, radar systems, remote sensing, internet of things (IoT), aviation and maritime navigation, WiFi® and Bluetooth®, or military and defense capabilities, or combinations thereof. The present subject matter has applicability to providing or enhancing security in such systems or associated devices, such as detecting potential vulnerabilities (e.g., “physical layer” attacks).

In one approach a method of detecting unauthorized Hardware Trojans can operate by exploiting features of wireless integrated circuits (ICs), such as inherent behavior associated with a wireless IC. Analysis of features such as antenna reflection coefficient (S₁₁) magnitude and phase measurements outside of an IC's normal operational frequency can be exploited to detect HTs.

In an example, a machine-implemented method can include generating a wireless transmission including a range of different frequencies to probe a device under test for a presence or an absence of unauthorized wireless hardware, receiving reflections elicited by the wireless transmission from the device under test; storing data representative of the received reflections, applying a machine learning model to the stored data, and, in response, detecting the presence or the absence of the unauthorized wireless hardware using an output of the machine learning model.

In an example, a system for detecting unauthorized wireless hardware can include a transmitter configured to generate wireless transmissions including a range of different frequencies, a receiver configured to receive reflections elicited by the wireless transmissions from a device under test, a memory configured to store data representative of the received reflections, and processing circuitry configured to apply a machine learning model to the stored data and detect a presence or an absence of unauthorized wireless hardware in the device under test using an output of the machine learning model.

In an example, a machine-implemented method for training a machine learning model for unauthorized wireless hardware detection can include obtaining first measurement data from wireless transmissions reflected by one or more reference devices without unauthorized wireless hardware, obtaining second measurement data from wireless transmissions reflected by one or more reference devices including unauthorized wireless hardware, and training the machine learning model using the first measurement data and the second measurement data to distinguish between devices with and without unauthorized wireless hardware.

This summary is intended to provide an overview of subject matter of the present patent application. It is not intended to provide an exclusive or exhaustive explanation of the invention. The detailed description is included to provide further information about the present patent application.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates generally an example comprising a system, such as can be used to perform detection of unauthorized wireless hardware in an electronic device.

FIG. 2 illustrates generally examples of interrogation of an electronic device under test to detect unauthorized wireless hardware, such as using a system as shown in FIG. 1.

FIG. 3A and FIG. 3B show respective illustrative examples of a printed circuit board (PCB) assembly used as a device under test (DUT) for evaluation of the techniques described in this document, with FIG. 3A showing a Hardware Trojan circuit populated with components and FIG. 3B showing the Hardware Trojan circuit region unpopulated.

FIG. 4A illustrates generally an illustrative example comprising a test setup where a wireless transceiver is arranged at a specified distance from a device under test (DUT) using a fixture.

FIG. 4B and FIG. 4C illustrate generally two different device under test (DUT) orientations used for training a machine learning model using the test setup shown in FIG. 4A.

FIG. 5A and FIG. 5B illustrate respective in-phase and quadrature digitized timeseries signals received using a RADAR receiver, including time series signals obtained with and without HT circuitry populated on the printed circuit board (PCB) assemblies of FIG. 3A and FIG. 3B.

FIG. 6 illustrates differences between the time series obtained with and without HT circuitry populated for the in-phase (FIG. 5A) and quadrature (FIG. 5B) measurements.

FIG. 7 illustrates generally a technique, such as a machine-implemented method, that can be used to detect a presence or absence of unauthorized wireless hardware using an output of a machine learning model.

FIG. 8 illustrates generally a technique, such as a machine-implemented method, that can be used to train a machine learning model for use in detecting a presence or absence of unauthorized wireless hardware.

FIG. 9 illustrates a block diagram of an example comprising a machine upon which any one or more of the techniques (e.g., methodologies) discussed herein may be performed.

### DETAILED DESCRIPTION

The rapid advancement of Internet of Things (IoT) devices has transformed multiple industries; however, the integration of IoT technology has introduced significant security challenges. The physical-layer (PHY) security of IoT devices is vulnerable to malicious hardware modifications, which can be referred to as Hardware Trojans (HTs). Given the unpredictable nature of HTs, the present inventors have recognized that countermeasures can be implemented, such as using radio-frequency fingerprint-based identification methods. The present subject matter can provide apparatus and techniques for detecting HTs embedded in wireless devices. The approaches described herein can use, for example, millimeter-wave (“mmWave”) RADAR (Radio-Aided Detection and Ranging) hardware measurements far outside the operating frequency range of the radar. HT detection using RADAR is demonstrated using a commercial-off-the-shelf mmWave RADAR, which transmits and receives reflected signals from a passive wireless module comprising a WiFi system-on-chip (ESP8285). The module also includes a custom-made IEEE 802.11 WiFi system-on-chip with signal conditioning components and a Hardware Trojan that disrupts the communication link by shorting the antenna. Decision Tree-based machine-learning approaches are used to successfully identify the presence of HTs from data provided by RADAR measurements, demonstrating usefulness for large-scale analyses and providing a reliable solution to PHY security challenges.

Unintended or malicious antennas, or Hardware Trojans (HTs) in general, can pose threats to systems if left undetected or unmitigated. The present inventors have recognized that the present subject matter can be used to identify a potential presence of HTs in systems as a security mechanism, such as before the HTs can pose any threats. The present subject matter can be integrated as a scanner element in a system that actively checks the environment such as providing an indication of a count or presence of antennas, or other indicia of HTs. As an example, RADAR scanning can be used to transmit wireless signals and record corresponding reflected signals. These measurements can provide an indication of unique radio frequency (RF) fingerprints of antennas embedded in the captured signal. The measurements can be provided to a trained machine-learning model that can detect a presence of the antennas or HTs, such as identifying a count of antennas present, or providing other indicia of a presence or absence of an HT. Use of “RF” is generic and does not require that the frequencies associated with the fingerprint are less than 1 GHz, for example. As mentioned above, frequency ranges of interest can include microwave (GHz) or millimeter wave (tens of GHz) frequencies, as an illustration.

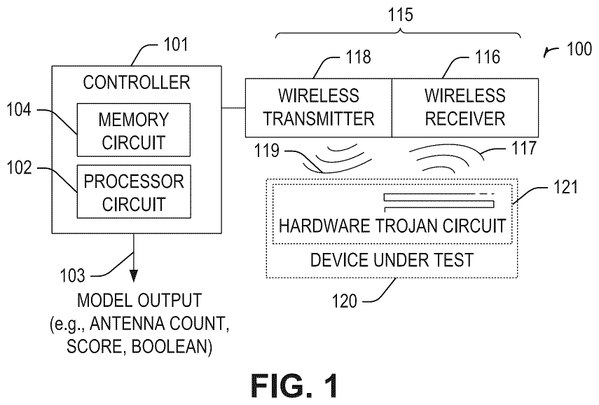

FIG. 1 illustrates generally an example comprising a system 100, such as can be used to perform detection of unauthorized wireless hardware in an electronic device. For example, a device under test (DUT) 120 can include a “Hardware Trojan” HT 121, such as can be detected by detected by the system 100. The system 100 can include a controller 101, such as including a memory circuit 104 or other storage and a processor circuit 102. The controller 101 can instantiate a machine learning model. The controller 101 can be communicatively coupled with a wireless transmitter 118 and a wireless receiver 116, such as a transceiver 115 (e.g., a RADAR module or other wireless transmitter/receiver). A transmitted signal 119 can be generated by the wireless transmitter 118, such as including a range of different frequencies (e.g., either contemporaneously or using a swept-frequency stimulus such as an output from a frequency modulated continuous wave (FMCW) RADAR). Reflections 117 elicited by the transmitted signal 119 can be detected by the wireless receiver 116. The reflections 117 need not be in the same range of frequencies as are used by the HT 121 or other portions of the DUT 120. A model output 103 from a machine learning model instance can be generated, such as using a stored representation of the reflections 117 (e.g., in-phase and quadrature time series representations obtained using the wireless receiver) as an input to the machine learning model. As discussed elsewhere herein, one or more model instances can be trained to detect a fingerprint associated with a reference device or with an HT, and the model output 103 can provide an indication when the fingerprint is detected (or absent). Such an indication can include a count of detected HTs or antennas congruent with a fingerprint, a boolean indication, or a score such as an anomaly score indicated of divergence of a detected signature from a reference fingerprint, as illustrative examples.

As an illustrative example, the present subject matter can be implemented using millimeter-wave (“mmWave”) RADAR (Radio-Aided Detection and Ranging) hardware, such as operating in a frequency range of 60 GHz to 64 GHz or using another range of frequencies. A RADAR transmitter and receiver can be used to scan a test area. If the test area contains an antenna, then its corresponding unique fingerprint can be detected and recorded. This fingerprint can be captured in the reflected waves elicited by a RADAR transmitter transmission and recorded by a RADAR receiver in the raw data captured. A machine learning technique can be used, such as where a model is trained to trace unique features of an antenna to identify it. A fingerprint can be used to differentiate detected antennas from each other. In general, the present subject can include using a combination of statistical analysis and machine-learning models, such that malicious hardware can be detected without previous knowledge of the HT characteristics.

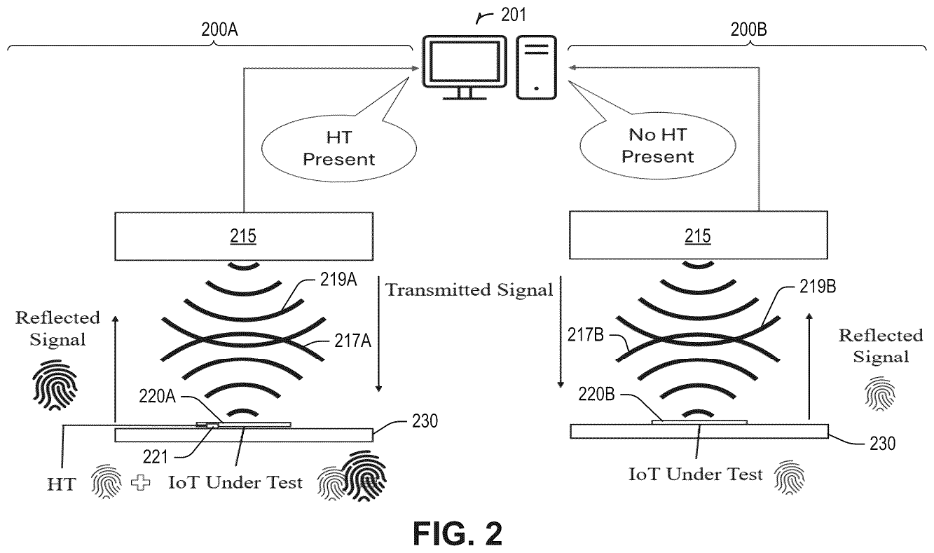

FIG. 2 illustrates generally examples of interrogation of an electronic device under test to detect unauthorized wireless hardware, such as using a system 100 as shown in FIG. 1. A controller 201 can be used to determine if an HT is present or absent, such as using a fingerprinting approach. Fingerprinting-based approaches can be used as countermeasures for HTs due to their low cost, low complexity, and nondestructive nature. These detection methods use inherent features of the integrated circuit (IC) to create a fingerprint that can detect hardware modifications. Characteristics such as timing, power consumption, temperature, optics, or electromagnetic radiation can be used as antenna fingerprints to develop countermeasures for malicious hardware. One approach can use side-channel analysis of antenna S₁₁ magnitude measurements to detect modules with HT modifications. By analyzing antenna characteristics far outside the operating frequency, Hardware Trojans can be detected more easily using correlation coefficients and Euclidean and Manhattan distances. In general, a range of different frequencies used for the wireless transmission can be the same or different from a frequency range used for receiving the reflections. A frequency range of operation of the device under test can be far less than the frequencies used for wireless transmission. For example, the frequency range of operation of the device under test can be less than 10 GHz, and the frequencies used for the transmission signal can be more than 60 GHz. Reflections elicited by the wireless transmission can occur passively, without requiring the unauthorized wireless hardware to be energized, or without requiring the DUT itself to be energized.

As an illustration, a mmWave frequency-modulated continuous wave (FMCW) RADAR was evaluated for the measurements due to its non-invasiveness, subsurface detection ability, wide availability, and compact size, which makes it convenient and efficient to integrate into security measurements. Such mmWave RADARs are used in other applications for detection and identification in health care, material detection, object detection, facial recognition, motion detection, and object tracking. The detection approach used for evaluation herein is shown schematically in FIG. 2. An HT 221 can be detected in an IoT device using RADAR techniques. Printed circuit boards (PCB) were fabricated based on commercial-off-the-shelf (COTS) modules that include a WiFi system-on-chip (SoC) and conditioning components, some of which include an HT 221 that short-circuits the antenna upon activation. A singular antenna included as a portion of the RADAR transceiver 215 captures the variations of the reflected signals 217A and 217B reflected off the radios 220A and 220B. The measured data is then analyzed to detect the presence of HTs using a machine-learning classification model. The experimental results described below, herein, illustrate that the malicious hardware can be detected as an abnormal behavior of the antenna fingerprint far beyond the radar's operating frequency, achieving 99.5% classification accuracy on both the validation and test datasets. For large-scale HT detection applications, machine learning classifiers can be trained with data from Trojan-free modules (as reference devices) to detect Trojan-infected units.

As shown in FIG. 2, in a first example 200A, the presence of HT 221 results in a different reflected signal 217A elicited by the wireless transmission signal 219A, as compared to the second example 200B, resulting in a different combined fingerprint. By contrast, in the second example 200B, the transmitted signal 219B elicits reflected signal 217B corresponding to a fingerprint that is more congruent with a reference device lacking the HT 221. A fixture 230 can be used to place the radios 220A and 220B at a specified distance from the RADAR transceiver 215.

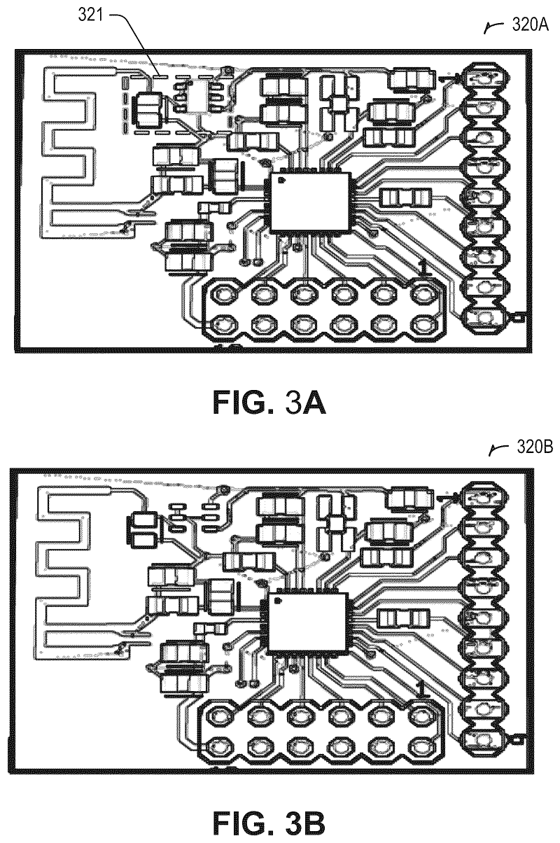

FIG. 3A and FIG. 3B show respective illustrative examples of a printed circuit board (PCB) assembly used as a device under test (DUT) for evaluation of the techniques described in this document, with FIG. 3A showing a wireless module 320A having a Hardware Trojan circuit (HT) 321 populated with components and FIG. 3B showing the wireless module 320B having the Hardware Trojan circuit region unpopulated. The wireless modules 320A and 320B are based on the ESP8285 IC (Espressif Systems, China), a system-on-chip (SoC) that supports 2.4 GHz WiFi (802.11 b/g/n) communications. The ESP8285 SoC includes RF conditioning components, such as a power amplifier and filters, a 32-bit processor, and on-chip SRAM in a 32-pin QFN package. Additionally, the modules 320A and 320B include a PCB antenna, making them self-contained systems capable of working in wireless network applications. The substrate chosen for the module is FR-4 with a dielectric constant of 4.5 and a loss tangent of 0.016, and the thicknesses of the substrate and the copper are 1.6 mm and 0.0356 mm, respectively, as specified by the PCB manufacturer. The compactness of the SoC minimizes the dimensions (32.6 mm×25.2 mm) and signal conditioning components of the 2-layer PCB design. Autodesk Fusion 360 PCB software was used to design the schematic and board layout. The HT 321 comprises an Analog Devices HMC550A switch (Analog Devices, Wilmington, MA), which allows control of signals from DC to 6 GHz with low insertion losses and current consumption. As shown in FIG. 3A, the switch is near the end of the antenna, providing an ability to short the antenna to ground (short-circuiting) in its powered-on state when it receives a control signal from the SoC. This emulates a malicious hardware element that can render the wireless functionality of the module 320A inoperable upon command.

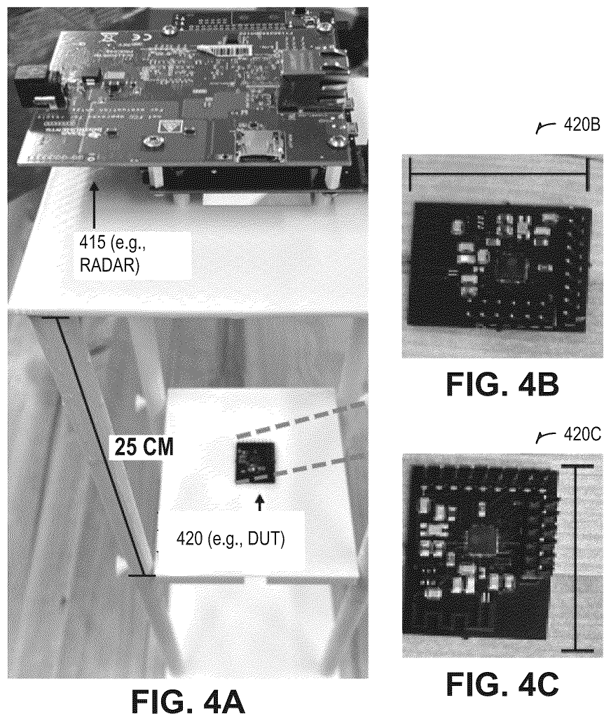

FIG. 4A illustrates generally an illustrative example comprising a test setup where a wireless transceiver 415 was arranged at a specified distance from a device under test (DUT) 420 using a fixture. FIG. 4B and FIG. 4C illustrate generally two different device under test (DUT) orientations, 420B in FIG. 4B (“horizontal”) and 420C in FIG. 4C (“vertical”), used for training a machine learning model using the test setup shown in FIG. 4A. Referring to FIG. 4A, the wireless transceiver 415 configuration shown provides an experimental setup for mmWave evaluation, with the wireless transceiver 415 comprising a MMWAVEICBOOST interface (Texas Instruments, Dallas, TX), combined with the IWR6843 antenna-on-package (AOP) EVM and DCA1000EVM, configured to operate at approximately 60-62 GHz. The AOP contains three transmit (TX) channels and four receive (RX) channels. For this experimental setup, one TX channel and one RX channel were employed. An additively manufactured test fixture was used as a controlled environment to conduct all experiments. The RADAR was placed facing down atop the fixture so that the AOP is perfectly aligned in the center of the holder. A flat surface was placed approximately 25 cm below the AOP on which the radios are positioned for testing. The surface on which the boards are placed was identical in each test, allowing its specific reflections to be a minor feature. The boards were measured in two different orientations: horizontal and vertical, as shown illustratively in FIG. 4B and FIG. 4C.

The Hardware Trojan detection method that was experimentally evaluated uses mmWave RADAR response measurements of the modules far outside the frequency of radar operation. The methodology uses the following approach, which includes data collection, comparison, and classification. In particular, the evaluation approach can include (1) performing mmWave RADAR measurements of the antenna of populated boards without the HT, (2) performing mmWave RADAR measurements of the antenna of populated boards with the HT, and (3) using a machine learning classification model to identify the Trojan-infected modules from the Trojan-free modules. The dataset was collected over multiple sessions to allow a variety of collection environments and ensure data integrity. The samples were divided into two primary portions: HT and No HT (NHT, without the presence of HT). Each group included two boards to allow for an unbiased and diverse dataset, resulting in four devices being tested: two HT and two NHTs. The measurement collection order was randomized with each iteration for further unbiased data measurements. A total of one hundred frames were utilized per measurement, each containing 128 FMCW chirps with 256 analog-to-digital converter (ADC) samples, thus producing 3,276,800 points for one test run. A minimum of ten readings were recorded for each test case to enhance the dataset further, allowing for many features to train and test the machine learning algorithm. The parameters used for collecting the data are shown below in TABLE 1.

TABLE 1
RADAR Sensor Configuration

| Parameter | Value | |
|---|---|---|
| Start Frequency | 60 | GHz |
| Number of Channels | 1 | |
| Chirp Duration | 100 | microseconds (μs) |
| Chirp Bandwidth | 2 | GHz |
| ADC Samples Per Frame | 256 | |
| Sample Rate | 2879 | kilosamples-per-second (Ksps) |

Data classification was performed using MATLAB's Classification Learner application, which provides access to various models, from simple decision trees to more complex methods. A 5-fold cross-validation method was employed, partitioning the dataset into five segments and computing the overall classification accuracy as the average accuracy across all folds. This approach reduces bias and ensures that the model's performance is not tied to any specific dataset partition.

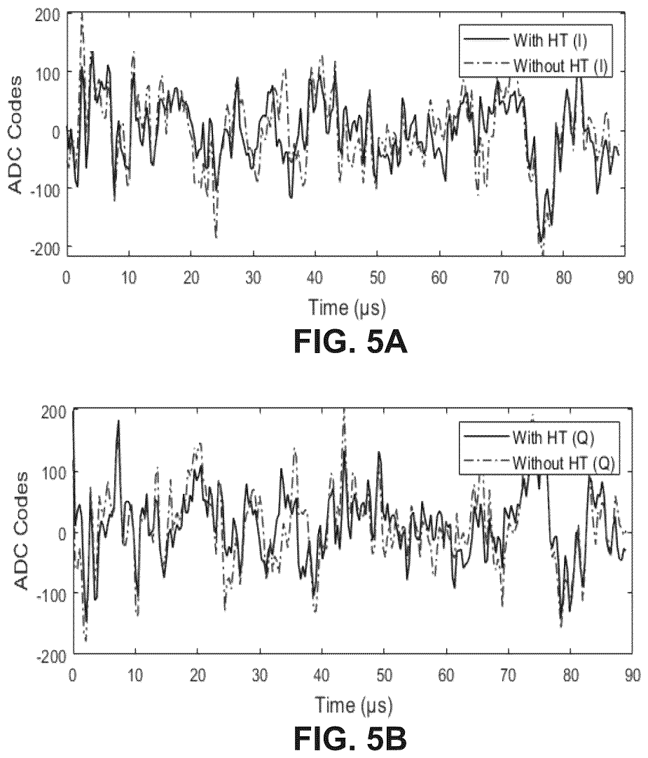

FIG. 5A and FIG. 5B illustrate respective in-phase and quadrature digitized timeseries signals received using a RADAR receiver, including time series signals obtained with and without HT circuitry populated on the printed circuit board (PCB) assemblies of FIG. 3A and FIG. 3B. An impact of the Hardware Trojan's presence on the radar signal can be observed in FIG. 5A and FIG. 5B, in which the time-domain radar measurement from two populated PCBs, with and without HTs, is presented. Such data represents the raw data collected from the radar; it shows the signal over time for one chirp. The RADAR records the raw signal in ADC codes, representing the binary values of the analog (voltage) input. For evaluation, both the in-phase (I) and quadrature (Q) data of the captured signal, were used to train and test the machine learning algorithm. Notably, discrepancies between the HT and NHT board signals can be seen. Although it is not clear by simple inspection what specific features are unique for each case, these variations, detectable across multiple time intervals within the chirp, suggest that the HT introduces subtle changes in the RADAR's signal reflection patterns that can be extracted as features by the machine learning algorithm for classification purposes.

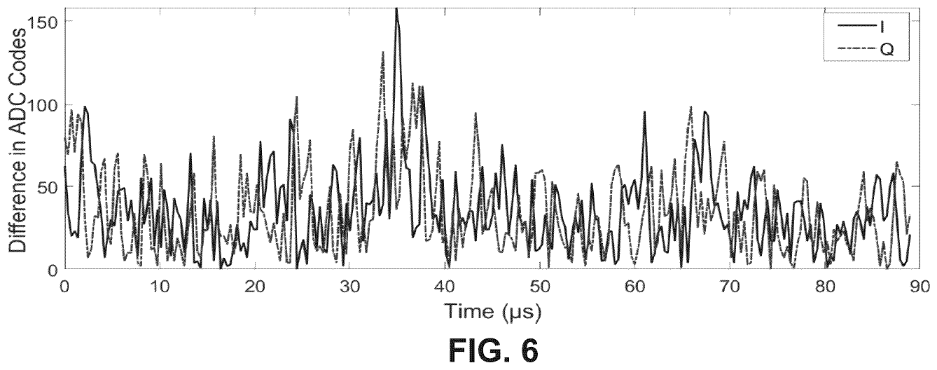

FIG. 6 illustrates differences between the time series obtained with and without HT circuitry populated for the in-phase (FIG. 5A) and quadrature (FIG. 5B) measurements. The ADC code difference of an HT and NHT board across one chirp is presented in FIG. 6. There were nine unique test cases: HT Board 1, HT Board 2, NHT Board 1, and NHT Board 2, each tested under two different orientations (horizontal and vertical), and an empty experiment tray served as a control. Ten samples were collected for each test case, resulting in 90 different readings. After carefully collecting all readings, the data was combined into one dataset, in which each row corresponds to a singular chirp with 256 ADC samples. Each reading recorded 128 chirps, giving a total of 11,520 chirps for all 90 readings. This produced a dataset with a 11,520×256 matrix. Only the first three chirps from each sample were used for the machine learning model's training and testing phases. This selection reduced the dataset size without sacrificing the features necessary for accurate classification. The reduced dataset was then passed through a decision tree classification algorithm, achieving a classification accuracy of 99.5% on both the validation and test datasets. TABLE 2 and TABLE 3 show the confusion matrices for validation and test cases. These results highlight the performance of the decision tree algorithm in terms of true positives, false positives, and misclassifications, demonstrating the consistency and accuracy of the model.

TABLE 2
Confusion Matrix (Validation Dataset)

| True Class versus Predicted Class | With HT | Without HT |
|---|---|---|
| With HT | 895 | 5 |
| Without HT | 4 | 896 |

TABLE 3
Confusion Matrix (Test Dataset)

| True Class versus Predicted Class | With HT | Without HT |
|---|---|---|
| With HT | 100 | 0 |
| Without HT | 1 | 99 |

While the radar signal changes are apparent between the difference signals shown in FIG. 6, these differences are closely tied to the specific HT configuration that was experimentally evaluated herein. For general applications, detection models would be trained and validated based on the HTs expected in the target system. The current method proves effective for the specific HT configuration tested. If a wider range of HT configurations are to be detected, common signal patterns or anomalies introduced by different HT designs could be evaluated, or transfer learning techniques could be employed to adapt models across various hardware setups, which could be validated with a larger number of PCBs for data collection. The impact of environmental factors, such as board orientation, proximity to other components, and real-world operational conditions, could also be validated.

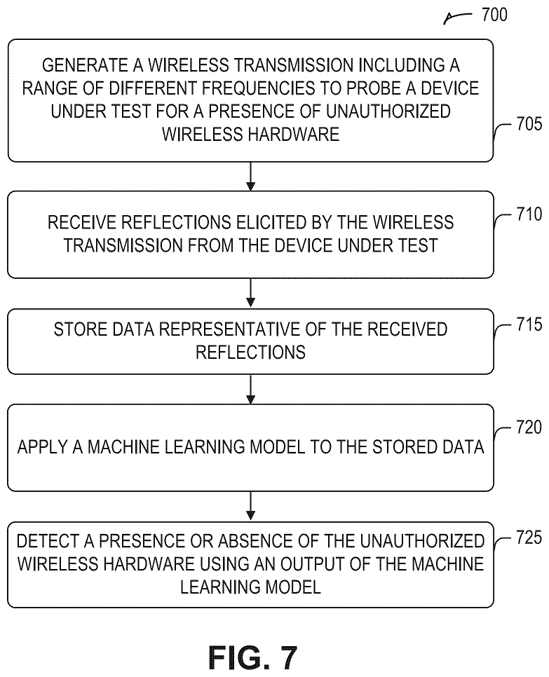

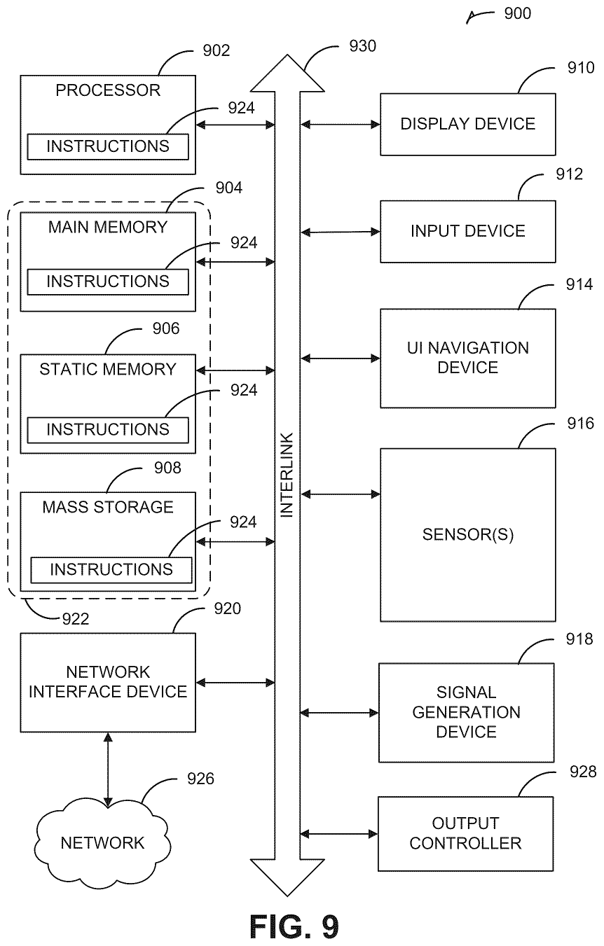

FIG. 7 illustrates generally a technique, such as a machine-implemented method 700 (such as can be implemented using the system 100 of FIG. 1 or the machine 900 of FIG. 9, or combinations thereof), that can be used to detect a presence or absence of unauthorized wireless hardware using an output of a machine learning model. At 705, a wireless transmission can be generated, including a range of different frequencies. The wireless transmission can be used to probe a device under test (DUT) for a presence or an absence of unauthorized wireless hardware. At 710, reflections elicited by the wireless transmission can be received from the device under test. This can include digitizing a narrow or wide bandwidth and can include down-converting the reflected signals to a frequency range suitable for an analog-to-digital converter. The digitization can be performed synchronously with the transmission, such as using a RADAR transmitter and receiver. At 715, data representative of the received reflections can be stored, such as time series representations corresponding to in-phase and quadrature received signals. As an illustration, if a chirped transmitter waveform is used, a received time series record can correspond to an integral count of chirp durations (e.g., 1, 2, 3, or “N” chirp durations). At 720, a machine learning model can applied to the stored data. For example, the machine learning model can include multiple inputs to receive the in-phase and quadrature time series representations. At 725, a presence or absence of unauthorized hardware can be detected using an output of the machine learning model. For example, the output can include an anomaly score (e.g., a score indicative of degree of deviation between an unknown input and a reference device used to train the machine learning model), or another numerical output such as a count of detected HTs, or a boolean output (e.g., a label “true” or “yes” indicative of the input matching the reference device and “false” or “no” indicating a presence of an HT, or vice versa).

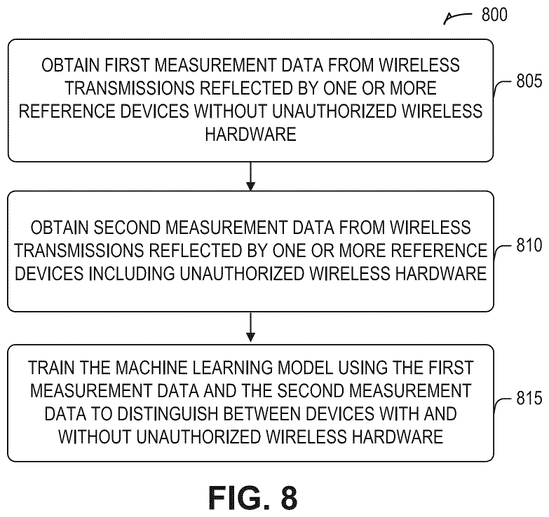

FIG. 8 illustrates generally a technique 800, such as a machine-implemented method, that can be used to train a machine learning model for use in detecting a presence or absence of unauthorized wireless hardware. At 805, first measurement data (e.g., time series data as discussed elsewhere herein) can be obtained corresponding to reflections from a reference device, elicited by wireless transmissions, where the first measurement data corresponds to reference devices without unauthorized wireless hardware. By contrast, at 810, second measurement data (e.g., also time series data) can be obtained corresponding to reflections from a reference device, elicited by wireless transmissions, where the second measurement data corresponds to reference devices including unauthorized wireless hardware. At 815, the machine learning model can be trained using the first measurement and the second measurement data, such as using a supervised or unsupervised learning approach, to establish a model that can distinguish between the devices with and without unauthorized wireless hardware. The trained model can then be instantiated in a system for performing HT detection as shown and described elsewhere herein. The technique 800 can be performed for a variety of different potential HT configurations, or for a variety of different reference device configurations, such as to provide models corresponding to such different cases.

FIG. 9 illustrates a block diagram of an example comprising a machine 900 upon which any one or more of the techniques (e.g., methodologies) discussed herein may be performed. Machine 900 (e.g., computer system) may include a hardware processor 902 (e.g., a central processing unit (CPU), a graphics processing unit (GPU), a hardware processor core, or any combination thereof), a main memory 904 and a static memory 906, connected via an interlink 930 (e.g., link or bus), as some or all of these components may constitute hardware for systems or related implementations discussed above.

Generally, the hardware processor 902 may, for example, include at least one of a Central Processing Unit (CPU), a Reduced Instruction Set Computing (RISC) Processor, a Complex Instruction Set Computing (CISC) Processor, a Graphics Processing Unit (GPU), a Digital Signal Processor (DSP), a Tensor Processing Unit (TPU), a Neural Processing Unit (NPU), a Vision Processing Unit (VPU), a Machine Learning Accelerator, an Artificial Intelligence Accelerator, an Application Specific Integrated Circuit (ASIC), a Field Programmable Gate Array (FPGA), a Radio-Frequency Integrated Circuit (RFIC), a Neuromorphic Processor, a Quantum Processor, or any combination thereof. A processor circuit may further be a multi-core processor having two or more independent processors (sometimes referred to as “cores”) that may execute instructions contemporaneously. Multi-core processors contain multiple computational cores on a single integrated circuit die, each of which can independently execute program instructions in parallel. Parallel processing on multi-core processors may be implemented via architectures like superscalar, VLIW, vector processing, or SIMD that allow each core to run separate instruction streams concurrently. A processor circuit may be emulated in software, running on a physical processor, as a virtual processor or virtual circuit. The virtual processor may behave like an independent processor but is implemented in software rather than hardware.

Specific examples of main memory 904 include Random Access Memory (RAM), and semiconductor memory devices, which may include storage locations in semiconductors such as registers. Specific examples of static memory 906 include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; RAM; or optical media such as CD-ROM and DVD-ROM disks.

The machine 900 may further include a display device 910, an input device 912 (e.g., a keyboard), and a user interface (UI) navigation device 914 (e.g., a mouse). In an example, the display device 910, input device 912, and UI navigation device 914 may be a touch-screen display. The machine 900 may include a mass storage device 908 (e.g., drive unit), a signal generation device 918 (e.g., a speaker), a network interface device 920, and one or more sensors 916, such as a global positioning system (GPS) sensor, compass, accelerometer, or some other sensor. The machine 900 may include an output controller 928, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The mass storage device 908 may comprise a machine-readable medium 922 on which is stored one or more sets of data structures or instructions 924 (e.g., software) embodying or utilized by any one or more of the techniques or functions described herein. The instructions 924 may also reside, completely or at least partially, within the main memory 904, within static memory 906, or within the hardware processor 902 during execution thereof by the machine 900. In an example, one or any combination of the hardware processor 902, the main memory 904, the static memory 906, or the mass storage device 908 comprises a machine readable medium.

Specific examples of machine-readable media include, one or more of non-volatile memory, such as semiconductor memory devices (e.g., EPROM or EEPROM) and flash memory devices; magnetic disks, such as internal hard disks and removable disks; magneto-optical disks; RAM; or optical media such as CD-ROM and DVD-ROM disks. While the machine-readable medium is illustrated as a single medium, the term “machine readable medium” may include a single medium or multiple media (e.g., a centralized or distributed database, or associated caches and servers) configured to store the one or more instructions 924.

An apparatus of the machine 900 includes one or more of a hardware processor 902 (e.g., a central processing unit (CPU), a graphics processing unit (GPU), a hardware processor core, or any combination thereof), a main memory 904 and a static memory 906, sensors 916, network interface device 920, antennas, a display device 910, an input device 912, a UI navigation device 914, a mass storage device 908, instructions 924, a signal generation device 918, or an output controller 928. The apparatus may be configured to perform one or more of the methods or operations disclosed herein.

The term “machine readable medium” includes, for example, any medium that is capable of storing, encoding, or carrying instructions for execution by the machine 900 and that cause the machine 900 to perform any one or more of the techniques of the present disclosure or causes another apparatus or system to perform any one or more of the techniques, or that is capable of storing, encoding or carrying data structures used by or associated with such instructions. Non-limiting machine-readable medium examples include solid-state memories, optical media, or magnetic media. Specific examples of machine-readable media include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); or optical media such as CD-ROM and DVD-ROM disks. In some examples, machine readable media includes non-transitory machine-readable media. In some examples, machine readable media includes machine readable media that is not a transitory propagating signal.

The instructions 924 may be transmitted or received, for example, over a communications network 926 using a transmission medium via the network interface device 920 utilizing any one of a number of transfer protocols (e.g., frame relay, internet protocol (IP), transmission control protocol (TCP), user datagram protocol (UDP), hypertext transfer protocol (HTTP), etc.). Example communication networks include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.11 family of standards known as Wi-Fi®), IEEE 802.15.4 family of standards, a Long Term Evolution (LTE) 4G or 5G family of standards, a Universal Mobile Telecommunications System (UMTS) family of standards, peer-to-peer (P2P) networks, satellite communication networks, among others.

In an example, the network interface device 920 includes one or more physical jacks (e.g., Ethernet, coaxial, or other interconnection) or one or more antennas to access the communications network 926. In an example, the network interface device 920 includes one or more antennas to wirelessly communicate using at least one of single-input multiple-output (SIMO), multiple-input multiple-output (MIMO), or multiple-input single-output (MISO) techniques. In some examples, the network interface device 920 wirelessly communicates using Multiple User MIMO techniques. The term “transmission medium” shall be taken to include any intangible medium that is capable of storing, encoding or carrying instructions for execution by the machine 900, and includes digital or analog communications signals or other intangible medium to facilitate communication of such software.

### Various Notes

Example 1 can include or use subject matter (such as a machine-implemented method) that comprises generating a wireless transmission including a range of different frequencies to probe a device under test for a presence or an absence of unauthorized wireless hardware, receiving reflections elicited by the wireless transmission from the device under test, storing data representative of the received reflections, applying a machine learning model to the stored data, and, in response, detecting the presence or the absence of the unauthorized wireless hardware using an output of the machine learning model.

Example 2 can include, or can optionally be combined with the subject matter of Example 1, to optionally include that the output of the machine learning model comprises a label or a value indicative of the presence or the absence of the unauthorized wireless hardware.

Example 3 can include, or can optionally be combined with the subject matter of one or any combination of Examples 1 or 2, to optionally include that the machine learning model is configured to detect an antenna fingerprint corresponding to an antenna of the unauthorized wireless hardware.

Example 4 can include, or can optionally be combined with the subject matter of one or any combination of Examples 1 through 3, to optionally include that the range of different frequencies used for the wireless transmission is different from a frequency range used for receiving the reflections.

Example 5 can include, or can optionally be combined with the subject matter of one or any combination of Examples 1 through 4, to optionally include that the wireless transmission is in a millimeter wave frequency range and the unauthorized wireless hardware is configured to operate at a frequency below 10 GHz.

Example 6 can include, or can optionally be combined with the subject matter of one or any combination of Examples 1 through 5, to optionally include that the reflections occur passively without requiring the unauthorized wireless hardware to be energized.

Example 7 can include, or can optionally be combined with the subject matter of one or any combination of Examples 1 through 6, to optionally include that the wireless transmission comprises one or more chirps.

Example 8 can include, or can optionally be combined with the subject matter of one or any combination of Examples 1 through 7, to optionally include that the stored data corresponds to a time-domain measurement of the reflections.

Example 9 can include, or can optionally be combined with the subject matter of Example 8, to optionally include that the stored data comprises in-phase and quadrature time-domain measurements of the reflections provided as inputs to the machine learning model.

Example 10 can include or use subject matter such as a system for detecting unauthorized wireless hardware that comprises a transmitter configured to generate wireless transmissions including a range of different frequencies, a receiver configured to receive reflections elicited by the wireless transmissions from a device under test, a memory configured to store data representative of the received reflections, and processing circuitry configured to apply a machine learning model to the stored data and detect a presence or an absence of unauthorized wireless hardware in the device under test using an output of the machine learning model.

Example 11 can include, or can optionally be combined with the subject matter of Example 10, to optionally include that the transmitter and receiver are configured to operate in a millimeter wave frequency range and the unauthorized wireless hardware is configured to operate at a frequency below 10 GHz.

Example 12 can include, or can optionally be combined with the subject matter of Example 11, to optionally include that the transmitter and the receiver are configured to operate at frequencies between 60 GHz and 64 GHz.

Example 13 can include, or can optionally be combined with the subject matter of Example 10, to optionally include that the transmitter is configured to transmit signals comprising a plurality of chirps.

Example 14 can include, or can optionally be combined with the subject matter of Example 10, to optionally include a fixture configured to position the device under test at a specified distance from the transmitter and the receiver.

Example 15 can include, or can optionally be combined with the subject matter of Example 10, to optionally include that the processing circuitry is configured to detect the unauthorized wireless hardware by analyzing time-domain measurements of the received reflections using the machine learning model.

Example 16 can include, or can optionally be combined with the subject matter of Example 10, to optionally include that the machine learning model generates an output indicative of a presence or an absence of an antenna fingerprint corresponding to the unauthorized wireless hardware.

Example 17 can include or use subject matter such as a machine-implemented method for training a machine learning model for unauthorized wireless hardware detection that comprises obtaining first measurement data from wireless transmissions reflected by one or more reference devices without unauthorized wireless hardware, obtaining second measurement data from wireless transmissions reflected by one or more reference devices including unauthorized wireless hardware, and training the machine learning model using the first measurement data and the second measurement data to distinguish between devices with and without unauthorized wireless hardware.

Example 18 can include, or can optionally be combined with the subject matter of Example 17, to optionally include that a range of different frequencies used for the wireless transmissions is different from a frequency range corresponding to the first measurement data and the second measurement data.

Example 19 can include, or can optionally be combined with the subject matter of Example 17, to optionally include that the first measurement data and the second measurement data are collected from the reference devices in multiple orientations.

Example 20 can include, or can optionally be combined with the subject matter of Example 17, to optionally include that the machine learning model comprises a decision tree classification model.

Each of the non-limiting Examples above can stand on its own or can be combined in various permutations or combinations with one or more of the other aspects or other subject matter described in this document.

The above detailed description includes references to the accompanying drawings, which form a part of the detailed description. The drawings show, by way of illustration, specific embodiments in which the invention can be practiced. These embodiments are also referred to generally as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc., are used merely as labels, and are not intended to impose numerical requirements on their objects.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Such instructions can be read and executed by one or more processors to enable performance of operations comprising a method, for example. The instructions are in any suitable form, such as but not limited to source code, compiled code, interpreted code, executable code, static code, dynamic code, and the like. Further, in an example, the code can be tangibly stored on one or more volatile, non-transitory, or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

The claimed invention is:

1. A machine-implemented method, comprising:
generating a wireless transmission including a range of different frequencies to probe a device under test for a presence or an absence of unauthorized wireless hardware;
receiving reflections elicited by the wireless transmission from the device under test; storing data representative of the received reflections;
applying a machine learning model to the stored data; and
in response, detecting the presence or the absence of the unauthorized wireless hardware using an output of the machine learning model.

2. The machine-implemented method of claim 1, wherein the output of the machine learning model comprises a label or a value indicative of the presence or the absence of the unauthorized wireless hardware.

3. The machine-implemented method of claim 1, wherein the machine learning model is configured to detect an antenna fingerprint corresponding to an antenna of the unauthorized wireless hardware.

4. The machine-implemented method of claim 1, wherein the range of different frequencies used for the wireless transmission is different from a frequency range used for receiving the reflections.

5. The machine-implemented method of claim 1, wherein the wireless transmission is in a millimeter wave frequency range and the unauthorized wireless hardware is configured to operate at a frequency below 10 GHz.

6. The machine-implemented method of claim 1, wherein the reflections occur passively without requiring the unauthorized wireless hardware to be energized.

7. The machine-implemented method of claim 1, wherein the wireless transmission comprises one or more chirps.

8. The machine-implemented method of claim 1, wherein the stored data corresponds to a time-domain measurement of the reflections.

9. The machine-implemented method of claim 8, wherein the stored data comprises in-phase and quadrature time-domain measurements of the reflections provided as inputs to the machine learning model.

10. A system for detecting unauthorized wireless hardware, comprising:
a transmitter configured to generate wireless transmissions including a range of different frequencies;
a receiver configured to receive reflections elicited by the wireless transmissions from a device under test;
a memory configured to store data representative of the received reflections; and
processing circuitry configured to apply a machine learning model to the stored data and detect a presence or an absence of unauthorized wireless hardware in the device under test using an output of the machine learning model.

11. The system of claim 10, wherein the transmitter and receiver are configured to operate in a millimeter wave frequency range and the unauthorized wireless hardware is configured to operate at a frequency below 10 GHz.

12. The system of claim 11, wherein the transmitter and the receiver are configured to operate at frequencies between 60 GHz and 64 GHz.

13. The system of claim 10, wherein the transmitter is configured to transmit signals comprising a plurality of chirps.

14. The system of claim 10, further comprising a fixture configured to position the device under test at a specified distance from the transmitter and the receiver.

15. The system of claim 10, wherein the processing circuitry is configured to detect the unauthorized wireless hardware by analyzing time-domain measurements of the received reflections using the machine learning model.

16. The system of claim 10, wherein the machine learning model generates an output indicative of a presence or an absence of an antenna fingerprint corresponding to the unauthorized wireless hardware.

17. A machine-implemented method for training a machine learning model for unauthorized wireless hardware detection, comprising:
obtaining first measurement data from wireless transmissions reflected by one or more reference devices without unauthorized wireless hardware;
obtaining second measurement data from wireless transmissions reflected by one or more reference devices including unauthorized wireless hardware;
training the machine learning model using the first measurement data and the second measurement data to distinguish between devices with and without unauthorized wireless hardware.

18. The machine-implemented method of claim 17, wherein a range of different frequencies used for the wireless transmissions is different from a frequency range corresponding to the first measurement data and the second measurement data.

19. The machine-implemented method of claim 17, wherein the first measurement data and the second measurement data are collected from the reference devices in multiple orientations.

20. The machine-implemented method of claim 17, wherein the machine learning model comprises a decision tree classification model.
